(19) United States
(12) Patent Application Publication
(10) Pub. No.: US 2026/0371879 A1
(43) Pub. Date: Nov. 19, 2026

(54) DISPLAY DEVICE

(71) Applicant: Sharp Display Technology Corporation, Kameyama City (JP)

(72) Inventors: Takao SAITOH, Kameyama City (JP); Yohsuke KANZAKI, Kameyama City (JP); Masaki YAMANAKA, Kameyama City (JP); Masahiko MIWA, Kameyama City (JP); Yi SUN, Kameyama City (JP); Masaki FUJIWARA, Kameyama City (JP)

(21) Appl. No.: 19/750,680

(22) Filed: Jul. 22, 2026

Related U.S. Application Data
(63) Continuation of application No. 18/571,539, filed on Jul. 27, 2021, now Pat. No. 12,757,596.

(51) Int. Cl. H10K 59/131; H10K 59/80; H10K 102/00

(52) U.S. Cl. CPC H10K 59/131; H10K 59/873; H10K 2102/311

(57) ABSTRACT

A display device includes a resin substrate, a thin film transistor layer, and a light-emitting element layer. A frame region is provided surrounding a display region. A terminal portion is provided at an end portion of the frame region. A bending portion is provided between the display region and the terminal portion. A slit is provided at the bending portion in an inorganic insulating film. A resin filling film is provided at the bending portion. A plurality of lead wiring lines are provided on the resin filling film. Protrusions and recesses, each extending in a direction intersecting an extending direction of the bending portion, are alternately disposed in the extending direction of the bending portion on a surface of the resin filling film. At least one of the plurality of lead wiring lines is provided on a protrusion of the protrusions.

### TECHNICAL FIELD

The disclosure relates to a display device.

### BACKGROUND ART

In recent years, as a display device replacing a liquid crystal display device, a self-luminous organic electroluminescence (hereinafter also referred to as "EL") display device using an organic EL element is widely known. Among such organic EL display devices, a flexible organic EL display device in which an organic EL element or the like is formed on a resin substrate having flexibility is attracting attention. Here, in the organic EL display device, there is provided a frame region surrounding a rectangular display region for displaying an image, and reduction of the frame region is demanded. Additionally, with the flexible organic EL display device, for example, reducing the frame region by bending the frame region on the terminal portion side on which a plurality of terminals are arrayed has been proposed.

For example, PTL 1 discloses a display device in which an opening exposing an upper surface of a resin substrate is formed in an inorganic insulating film at a bending portion of the frame region, and a plurality of wiring lines extending parallel with each other in a direction intersecting an extending direction of the bending portion are provided on a surface of the inorganic insulating film and the upper surface of the resin substrate exposed from the opening.

### CITATION LIST

### PATENT LITERATURE PTL 1

WO 2019/163030

### SUMMARY

### Technical Problem

Incidentally, in the flexible organic EL display device, inorganic insulating films, such as a base coat film, a gate insulating film, and an interlayer insulating film, are provided on a resin substrate. Thus, in order to suppress disconnection of the wiring lines disposed in the frame region, the inorganic insulating films on a bending portion of the frame region are removed to suppress breakage of the inorganic insulating films in the bending portion, as in PTL 1 described above. Here, in the bending portion of the frame region, a plurality of wiring lines are provided extending parallel with each other in a direction intersecting the extending direction of the bending portion. However, in a structure in which a metal film constituting the wiring lines is likely to remain between adjacent wiring lines, the plurality of wiring lines may be short-circuited.

The disclosure has been made in view of the above, and an object of the disclosure is to suppress short-circuiting between wiring lines in a bending portion of a frame region.

### Solution to Problem

In order to achieve the object described above, a display device according to the disclosure includes a resin substrate, a thin film transistor layer provided on the resin substrate and including an inorganic insulating film, and a light-emitting element layer provided on the thin film transistor layer and arrayed with a plurality of light-emitting elements corresponding to a plurality of subpixels constituting a display region. A frame region is provided surrounding the display region. A terminal portion is provided at an end portion of the frame region. A bending portion is provided between the display region and the terminal portion, the bending portion extending in one direction. A slit is provided at the bending portion in the inorganic insulating film, the slit extending in an extending direction of the bending portion and exposing a surface of the resin substrate. A resin filling film is provided at the bending portion, the resin filling film filling the slit. A plurality of lead wiring lines are provided on the resin filling film, the plurality of lead wiring lines extending parallel with each other in a direction intersecting the extending direction of the bending portion. Protrusions and recesses, each extending in a direction intersecting the extending direction of the bending portion, are alternately disposed in the extending direction of the bending portion on a surface of the resin filling film. At least one of the plurality of lead wiring lines is provided on a protrusion of the protrusions.

### Advantageous Effects of Disclosure

According to the disclosure, it is possible to suppress short-circuiting between wiring lines in a bending portion of a frame region.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the organic EL display device taken along a line III-III in FIG. 1.

FIG. 4 is an equivalent circuit diagram of a thin film transistor layer constituting the organic EL display device according to the first embodiment of the disclosure.

FIG. 5 is a cross-sectional view of an organic EL layer constituting the organic EL display device according to the first embodiment of the disclosure.

FIG. 6 is a cross-sectional view of a frame region of the organic EL display device taken along a line VI−VI in FIG. 1.

FIG. 7 is a plan view of a bending portion of the frame region of the organic EL display device according to the first embodiment of the disclosure.

FIG. 8 is a cross-sectional view of the bending portion of the organic EL display device taken along a line VIII-VIII in FIG. 7.

FIG. 9 is a cross-sectional view of the bending portion of the organic EL display device taken along a line IX−IX in FIG. 7.

FIG. 10 is a cross-sectional view of the bending portion of the organic EL display device taken along line X-X in FIG. 7.

FIG. 11 is a cross-sectional view of a modified example of the organic EL display device according to the first embodiment of the disclosure, and is a view corresponding to FIG. 10.

FIG. 12 is a cross-sectional view of a bending portion of the organic EL display device according to a second embodiment of the disclosure, and is a view corresponding to FIG. 8.

FIG. 13 is a cross-sectional view of the bending portion of the organic EL display device according to the second embodiment of the disclosure, and is a view corresponding to FIG. 9.

FIG. 14 is a cross-sectional view of the bending portion of the organic EL display device according to the second embodiment of the disclosure, and is a view corresponding to FIG. 10.

### DESCRIPTION OF EMBODIMENTS

Embodiments of a technique according to the disclosure will be described below in detail with reference to the drawings. Note that the technique according to the disclosure is not limited to the embodiments described below.

### First Embodiment

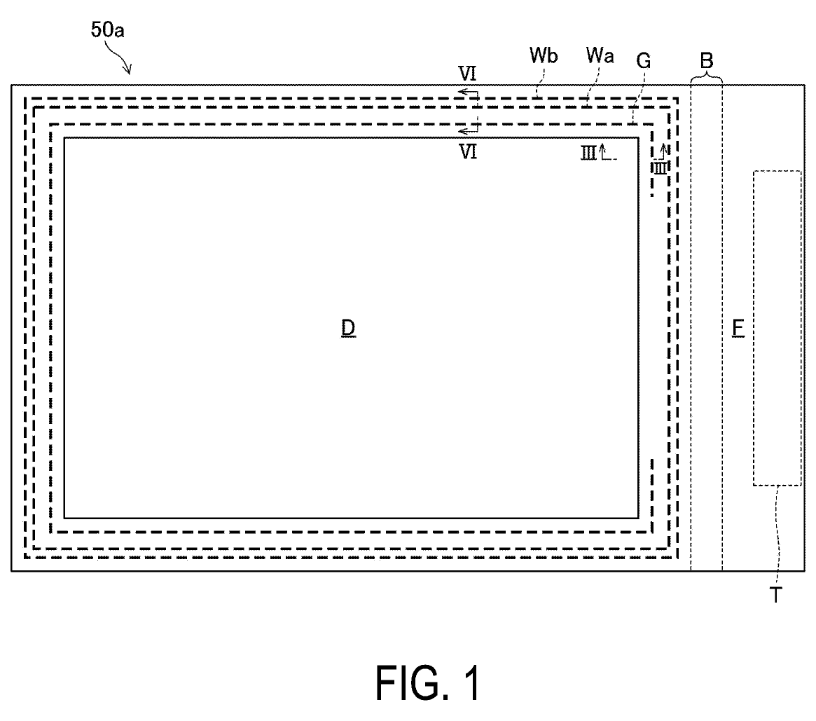

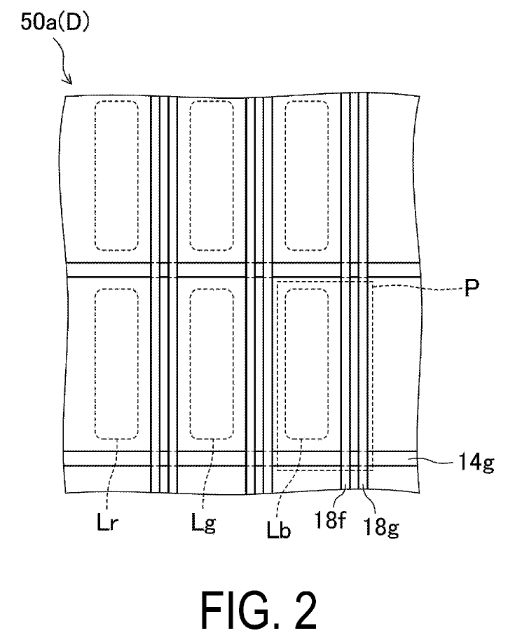

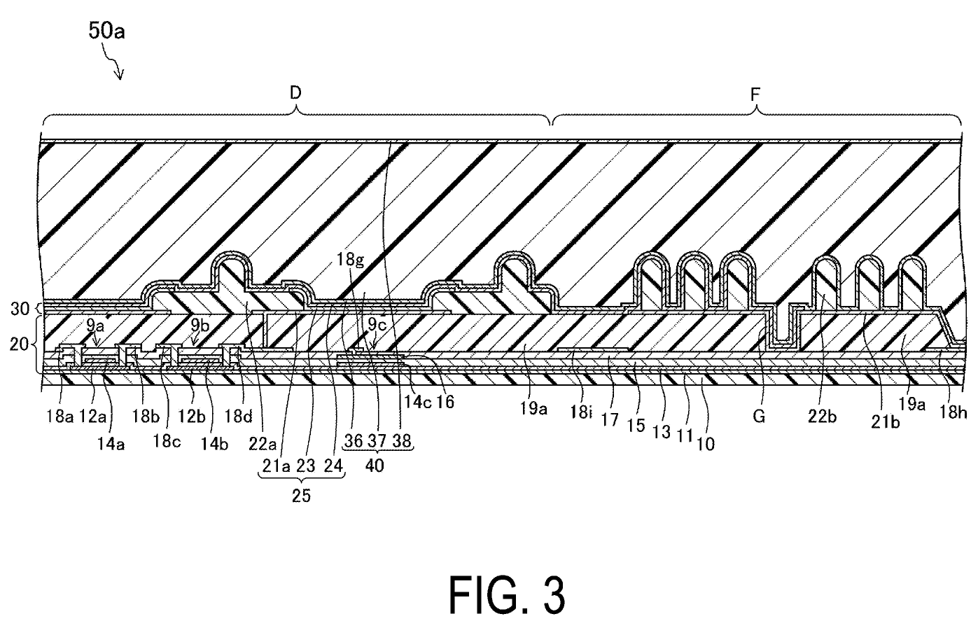

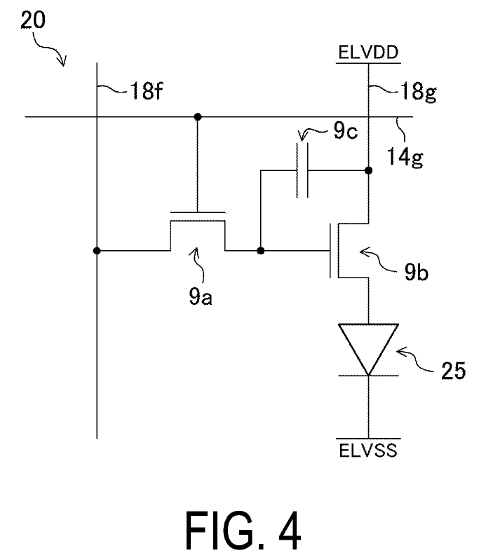

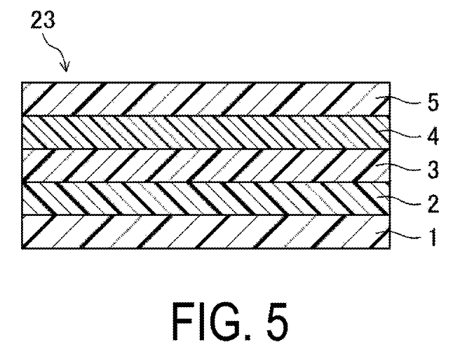

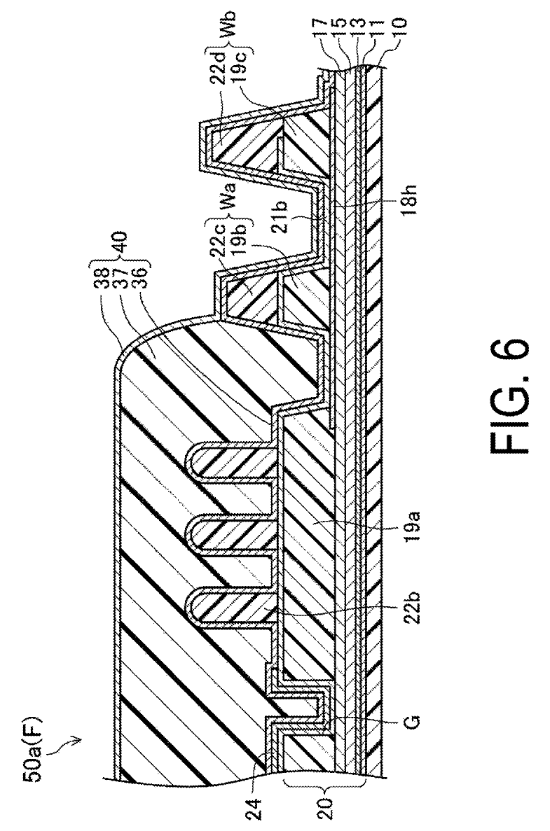

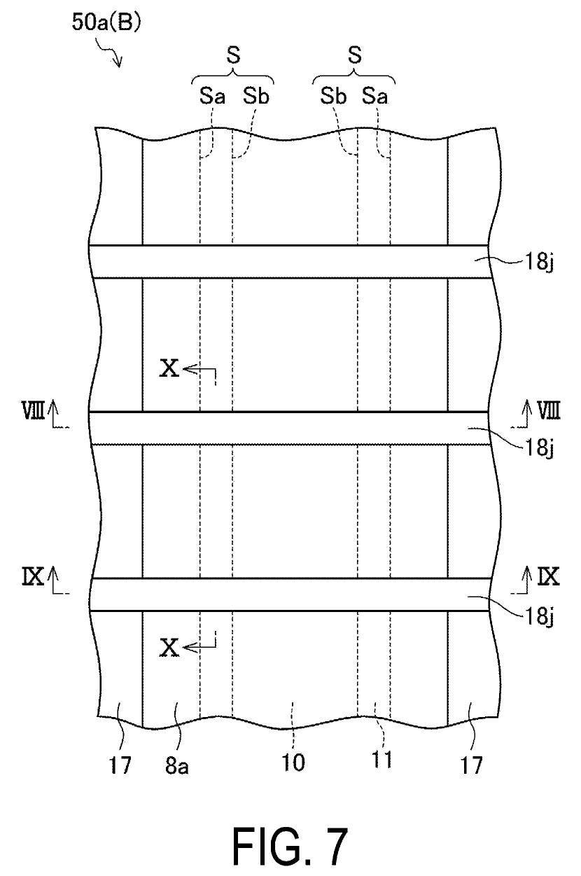

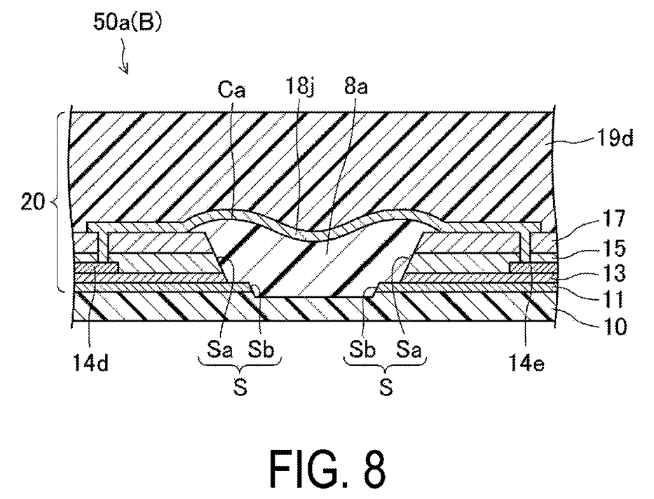

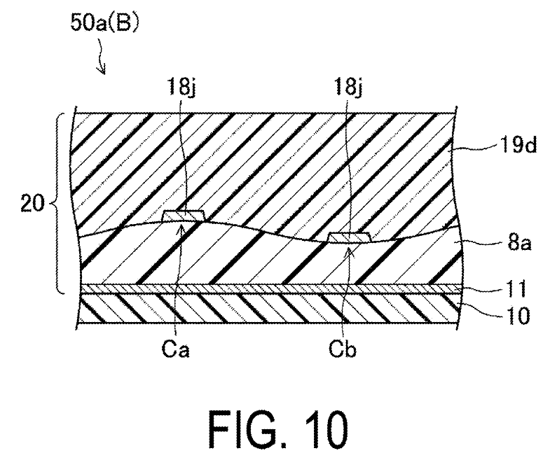

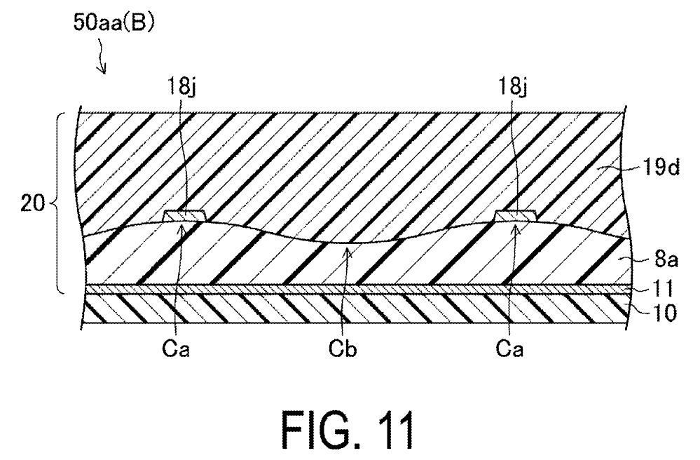

FIGS. 1-11 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50a according to the present embodiment. Further, FIG. 2 is a plan view of a display region D of the organic EL display device 50a. FIG. 3 is a cross-sectional view of the organic EL display device 50a taken along a line III−III in FIG. 1. FIG. 4 is an equivalent circuit diagram of a thin film transistor layer 20 constituting the organic EL display device 50a. Further, FIG. 5 is a cross-sectional view of an organic EL layer 23 constituting the organic EL display device 50a. FIG. 6 is a cross-sectional view of a frame region F of the organic EL display device 50a taken along a line VI-VI in FIG. 1. FIG. 7 is a plan view of a bending portion B of the frame region F of the organic EL display device 50a. FIGS. 8, 9, and 10 are cross-sectional views of the bending portion B of the organic EL display device 50a taken along a line VIII-VIII, a line IX-IX, and a line X-X in FIG. 7, respectively. Further, FIG. 11 is a cross-sectional view of an organic EL display device 50aa of a modified example of the organic EL display device 50a, and is a view corresponding to FIG. 10.

As illustrated in FIG. 1, the organic EL display device 50a includes, for example, the display region D that is provided in a rectangular shape and in which an image is displayed, and the frame region F provided in a frame-like shape surrounding the display region D. Note that, in the present embodiment, the display region D having the rectangular shape is exemplified, but the rectangular shape includes a substantially rectangular shape such as a shape whose sides are arc-shaped, a shape whose corners are arc-shaped, and a shape in which a part of a side has a notch, for example.

As illustrated in FIG. 2, a plurality of subpixels P are arrayed in a matrix shape in the display region D. In addition, in the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

A terminal portion T is provided in an end portion of the frame region F on the right side in FIG. 1, extending in one direction (vertical direction in the drawing). In addition, between the display region D and the terminal portion T, as illustrated in FIG. 1, that is, in the frame region F, the bending portion B bendable by, for example, 180 degrees (in a U-shape) with the vertical direction in the drawing as a bending axis is provided on the display region D side of the terminal portion T, extending in one direction (vertical direction in the drawing). Here, in the frame region F, in a flattening film 19a described below, a trench G having a substantially C shape in a plan view is provided passing through the flattening film 19a, as illustrated in FIGS. 1, 3, and 6. Note that, as illustrated in FIG. 1, the trench G is provided in a substantially C shape open on the terminal portion T side in a plan view.

As illustrated in FIGS. 3, 6, 8, 9, and 10, the organic EL display device 50a includes a resin substrate layer 10, the thin film transistor (hereinafter, also referred to as a TFT) layer 20 provided on the resin substrate 10, an organic EL element layer 30 provided as a light-emitting element layer on the TFT layer 20, and a sealing film 40 provided on the organic EL element layer 30.

The resin substrate 10 is made of, for example, a polyimide resin.

As illustrated in FIG. 3, the TFT layer 20 includes a base coat film 11 provided on the resin substrate 10 as an inorganic insulating film, a plurality of first TFTs 9a, a plurality of second TFTs 9b, and a plurality of capacitors 9c provided on the base coat film 11, and the flattening film 19a provided on each of the first TFTs 9a, each of the second TFTs 9b, and each of the capacitors 9c. Here, in the TFT layer 20, as illustrated in FIGS. 2 and 4, a plurality of gate lines 14g are provided extending parallel with each other in the horizontal direction in the drawings. In the TFT layer 20, as illustrated in FIGS. 2 and 4, a plurality of source lines 18f are provided as a wiring line layer, extending parallel with each other in the vertical direction in the drawings. Further, in the TFT layer 20, as illustrated in FIGS. 2 and 4, a plurality of power source lines 18g are provided as a wiring line layer, extending parallel with each other in the vertical direction in the drawings. Then, as illustrated in FIG. 2, each of the power source lines 18g is provided adjacent to one of the source lines 18f. Further, in the TFT layer 20, as illustrated in FIG. 4, each of the subpixels P includes the first TFT 9a, the second TFT 9b, and the capacitor 9c.

For example, the base coat film 11 and a gate insulating film 13, a first interlayer insulating film 15, and a second interlayer insulating film 17 described below are each composed of a single-layer film or a layered film of an inorganic insulating film of silicon nitride, silicon oxide, silicon oxynitride, or the like.

The first TFT 9a is electrically connected to the corresponding gate line 14g and source line 18f in each of the subpixels P, as illustrated in FIG. 4. Additionally, as illustrated in FIG. 3, the first TFT 9a includes a semiconductor layer 12a, the gate insulating film 13, a gate electrode 14a, the first interlayer insulating film 15, the second interlayer insulating film 17, and a source electrode 18a and a drain electrode 18b, which are sequentially provided on the base coat film 11. Here, as illustrated in FIG. 3, the semiconductor layer 12a is provided in an island shape on the base coat film 11 using a polysilicon film such as low-temperature polysilicon (LTPS), for example, and includes a channel region, a source region, and a drain region. In addition, as illustrated in FIG. 3, the gate insulating film 13 is provided as an inorganic insulating film, covering the semiconductor layer 12a. Additionally, as illustrated in FIG. 3, the gate electrode 14a is provided on the gate insulating film 13, overlapping the channel region of the semiconductor layer 12a. Additionally, as illustrated in FIG. 3, the first interlayer insulating film 15 and the second interlayer insulating film 17 are provided in this order as inorganic insulating films, covering the gate electrode 14a. Additionally, as illustrated in FIG. 3, the source electrode 18a and the drain electrode 18b are provided as wiring line layers, separated from each other on the second interlayer insulating film 17. Additionally, as illustrated in FIG. 3, the source electrode 18a and the drain electrode 18b are electrically connected to the source region and the drain region of the semiconductor layer 12a, respectively, via each contact hole formed in a layered film including the gate insulating film 13, the first interlayer insulating film 15, and the second interlayer insulating film 17.

The second TFT 9b is electrically connected to the corresponding first TFT 9a and power source line 18g in each of the subpixels P, as illustrated in FIG. 4. As illustrated in FIG. 3, the second TFT 9b includes a semiconductor layer 12b, the gate insulating film 13, a gate electrode 14b, the first interlayer insulating film 15, the second interlayer insulating film 17, and a source electrode 18c and a drain electrode 18d, which are provided in this order on the base coat film 11. Here, as illustrated in FIG. 3, the semiconductor layer 12b is provided in an island shape on the base coat film 11 using a polysilicon film such as LTPS, for example, and includes a channel region, a source region, and a drain region. Additionally, as illustrated in FIG. 3, the gate insulating film 13 is provided, covering the semiconductor layer 12b. Additionally, as illustrated in FIG. 3, the gate electrode 14b is provided on the gate insulating film 13, overlapping the channel region of the semiconductor layer 12b. Additionally, as illustrated in FIG. 3, the first interlayer insulating film 15 and the second interlayer insulating film 17 are sequentially provided, covering the gate electrode 14b. Additionally, as illustrated in FIG. 3, the source electrode 18c and the drain electrode 18d are provided as wiring line layers, separated from each other on the second interlayer insulating film 17. Additionally, as illustrated in FIG. 3, the source electrode 18c and the drain electrode 18d are electrically connected to the source region and the drain region of the semiconductor layer 12b, respectively, via each contact hole formed in a layered film including the gate insulating film 13, the first interlayer insulating film 15, and the second interlayer insulating film 17.

Note that, in the present embodiment, the first TFT 9a and the second TFT 9b are exemplified as being a top-gate type TFT, but the first TFT 9a and the second TFT 9b may be a bottom-gate type TFT.

The capacitor 9c is electrically connected to the corresponding first TFT 9a and power source line 18g in each of the subpixels P, as illustrated in FIG. 4. Here, as illustrated in FIG. 3, the capacitor 9c includes a lower conductive layer 14c made of the same material as that of the gate electrodes 14a and 14b and formed in the same layer as that of the gate electrodes 14a and 14b, the first interlayer insulating film 15 provided covering the lower conductive layer 14c, and an upper conductive layer 16 provided on the first interlayer insulating film 15 and overlapping the lower conductive layer 14c. Note that, as illustrated in FIG. 3, the upper conductive layer 16 is electrically connected to the power source line 18g via a contact hole formed in the second interlayer insulating film 17.

The flattening film 19a has a flat surface in the display region D and is made of, for example, an organic resin material such as a polyimide resin, or a polysiloxane-based spin on glass (SOG) material.

As illustrated in FIG. 3, the organic EL element layer 30 includes a plurality of organic EL elements 25 arrayed in a matrix shape in correspondence with the plurality of subpixels P as a plurality of light-emitting elements, and an edge cover 22a provided in a lattice pattern in common to all the subpixels P so as to cover a peripheral end portion of a first electrode 21a, described below, of each organic EL element 25.

As illustrated in FIG. 3, the organic EL element 25 includes, in each subpixel P, the first electrode 21a provided on the flattening film 19a of the TFT layer 20, the organic EL layer 23 provided on the first electrode 21a, and a second electrode 24 provided on the organic EL layer 23.

As illustrated in FIG. 3, the first electrode 21a is electrically connected to the drain electrode 18d of the second TFT 9b of each subpixel P via a contact hole formed in the flattening film 19a. The first electrode 21a has a function of injecting holes (positive holes) into the organic EL layer 23. The first electrode 21a is preferably made of a material having a large work function to improve the efficiency of hole injection into the organic EL layer 23. Examples of materials constituting the first electrode 21a include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material constituting the first electrode 21a may include alloys such as astatine (At)/astatine oxide (AtO₂). Furthermore, examples of materials constituting the first electrode 21a include electrically conductive oxides such as tin oxide (SnO), zinc oxide (ZnO), indium tin oxide (ITO), and indium zinc oxide (IZO). The first electrode 21a may also be formed by layering a plurality of layers made of any of the materials described above. Note that examples of compound materials having a high work function include indium tin oxide (ITO) and indium zinc oxide (IZO).

As illustrated in FIG. 5, each organic EL layer 23 includes a hole injection layer 1, a hole transport layer 2, a light-emitting layer 3, an electron transport layer 4, and an electron injection layer 5, which are provided in that order on the first electrode 21a.

The hole injection layer 1 is also referred to as an anode buffer layer, and has a function of reducing an energy level difference between the first electrode 21a and the organic EL layer 23 to thereby improve the hole injection efficiency from the first electrode 21a into the organic EL layer 23. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the hole transport efficiency from the first electrode 21a to the organic EL layer 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where positive holes and electrons are injected from the first electrode 21a and the second electrode 24, respectively, and the holes and the electrons recombine, when a voltage is applied via the first electrode 21a and the second electrode 24. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of facilitating migration of electrons to the light-emitting layer 3 efficiently. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency of electron injection into the organic EL layer 23 from the second electrode 24, and the electron injection layer 5 can lower the drive voltage of the organic EL element 25 by this function. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 24 is provided covering each of the organic EL layers 23 and the edge cover 22a. In addition, the second electrode 24 has a function of injecting electrons into the organic EL layer 23. In addition, the second electrode 24 is preferably made of a material with a low work function to improve the efficiency of electron injection into the organic EL layer 23. Here, examples of materials constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be made of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al), for example. In addition, the second electrode 24 may be made of electrically conductive oxide such as tin oxide (SnO), zinc oxide (ZnO), indium tin oxide (ITO), indium zinc oxide (IZO), for example. In addition, the second electrode 24 may be formed by layering a plurality of layers made of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 22a is made of, for example, an organic resin material such as a polyimide resin or an acrylic resin, or a polysiloxane-based SOG material. Here, as illustrated in FIG. 3, part of a surface of the edge cover 22a projects upward in the drawing and is a pixel photo spacer provided in an island shape.

As illustrated in FIGS. 3 and 6, the sealing film 40 includes a first inorganic sealing film 36 provided covering the second electrode 24, an organic sealing film 37 provided on the first inorganic sealing film 36, and a second inorganic sealing film 38 provided covering the organic sealing film 37, and has a function of protecting the organic EL layer 23 from moisture, oxygen, and the like. Here, the first inorganic sealing film 36 and the second inorganic sealing film 38 are made of an inorganic material such as, for example, silicon oxide (SiO₂), aluminum oxide (Al₂O₃), silicon nitride (SiNx (where x is a positive number)) such as trisilicon tetranitride (Si₃N₄), or silicon carbonitride (SiCN). The organic sealing film 37 is made of an organic material such as an acrylic resin, a polyurea resin, a parylene resin, a polyimide resin, or a polyamide resin, for example.

Additionally, as illustrated in FIG. 1, the organic EL display device 50a includes, in the frame region F, a first dam wall Wa provided in a frame-like shape surrounding the display region D and overlapping a peripheral end portion of the organic insulating film 37, and a second dam wall Wb provided in a frame-like shape surrounding the first dam wall Wa.

As illustrated in FIG. 6, the first dam wall Wa includes a lower resin layer 19b made of the same material as that of the flattening film 19a and formed in the same layer as that of the flattening film 19a, and an upper resin layer 22c provided on the lower resin layer 19b with a conductive layer 21b interposed therebetween, made of the same material as that of the edge cover 22a, and formed in the same layer as that of the edge cover 22a. Here, as illustrated in FIG. 6, the conductive layer 21b is provided in a substantially C shape overlapping the trench G, the first dam wall Wa, and the second dam wall Wb in the frame region F. Note that the conductive layer 21b is made of the same material as that of the first electrode 21a and formed in the same layer as that of the first electrode 21a.

As illustrated in FIG. 6, the second dam wall Wb includes a lower resin layer 19c made of the same material as that of the flattening film 19a and formed in the same layer as that of the flattening film 19a, and an upper resin layer 22d provided on the lower resin layer 19c with the conductive layer 21b interposed therebetween, made of the same material as that of the edge cover 22a, and formed in the same layer as that of the edge cover 22a.

As illustrated in FIGS. 3 and 6, the organic EL display device 50a includes a first frame wiring line 18h provided as a wiring line layer in a substantially C shape outside of the trench G, with the first frame wiring line 18h surrounding the display region D and overlapping the first dam wall Wa and the second dam wall Wb in the frame region F. Here, the first frame wiring line 18h is configured to receive a low power supply voltage (ELVSS) in the terminal portion T. Further, as illustrated in FIG. 6, the first frame wiring line 18h is electrically connected to the second electrode 24 via the conductive layer 21b.

As illustrated in FIG. 3, the organic EL display device 50a includes a second frame wiring line 18i provided as a wiring line layer in a substantially C shape inside of the trench G in the frame region F. Here, the second frame wiring line 18i is configured to receive a high-power supply voltage (ELVDD) in the terminal portion T. The second frame wiring line 18i is electrically connected, on the display region D side, to the plurality of power source lines 18g disposed in the display region D.

Furthermore, as illustrated in FIGS. 7, 8, and 9, the organic EL display device 50a includes, in the bending portion B, a resin filling film 8a that fills a slit S formed in the base coat film 11, the gate insulating film 13, the first interlayer insulating film 15, and the second interlayer insulating film 17; a plurality of lead wiring lines 18j provided on the resin filling film 8a and the second interlayer insulating film 17; and a resin covering layer 19d covering the plurality of lead wiring lines 18j.

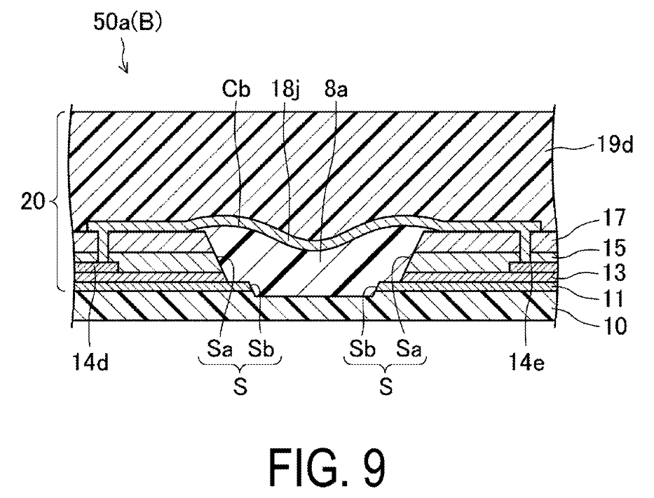

As illustrated in FIGS. 7, 8, and 9, the slit S is provided in a groove shape that passes through the base coat film 11, the gate insulating film 13, the first interlayer insulating film 15, and the second interlayer insulating film 17 and runs along an extending direction of the bending portion B, exposing a surface of the resin substrate 10. Here, as illustrated in FIGS. 7, 8 and 9, the slit S includes a first slit Sa in the gate insulating film 13, the first interlayer insulating film 15, and the second interlayer insulating film 17, exposing a surface of the base coat film 11, and a second slit Sb provided in the base coat film 11, exposing the surface of the resin substrate 10. Note that, as illustrated in FIGS. 8 and 9, the second slit Sb is also provided in the surface layer of the resin substrate 10.

The resin filling film 8a is made of an organic resin material such as a polyimide resin, for example. As illustrated in FIGS. 8 and 9, a surface of the resin filling film 8a is gradually increasingly lower than a surface of the second interlayer insulating film 17 outside of the slit S, from both end portions toward a central portion of the slit S in a width direction. Here, as illustrated in FIGS. 8, 9, and 10, protrusions Ca and recesses Cb, each extending in a direction orthogonal to the extending direction of the bending portion B, are alternately disposed in the extending direction of the bending portion B on the surface of the resin filling film 8a.

The plurality of lead wiring lines 18j extend parallel with each other at intervals of about 5 µm, for example, in a direction orthogonal to the extending direction of the bending portion B. Here, of the plurality of lead wiring lines 18j, one of a pair of lead wiring lines 18j adjacent to each other is provided on the protrusion Ca as illustrated in FIGS. 7 and 8, and the other of the pair of lead wiring lines 18j adjacent to each other is provided in the recess Cb as illustrated in FIGS. 7 and 9. Note that, in the organic EL display device 50a, in the washing performed before formation of the wiring line layers such as the source line 18f, foreign matters (for example, inorganic insulating film or metal film) are likely to accumulate on surfaces of inclined portions of the resin filling film 8a which lowers toward the central portion of the slit S, and the metal film of the wiring line layers is likely to remain on the surfaces of the inclined portions. However, even if metal film remains in the recesses Cb at relatively low positions of the surface of the resin filling film 8a, the metal film is unlikely to remain on the protrusions Ca of the resin filling film 18j at relatively high positions, making it possible to suppress short-circuiting between the lead wiring lines 18j adjacent to each other. Further, as illustrated in FIGS. 8 and 9, both end portions of each of the lead wiring lines 18j are electrically connected to a first gate conductive layer 14d and a second gate conductive layer 14e, respectively, via respective contact holes formed in a layered film of the first interlayer insulating film 15 and the second interlayer insulating film 17. Note that the lead wiring lines 18j are made of the same material as that of the wiring line layers such as the source line 18f and formed in the same layer as that of the wiring line layers such as the source line 18f. Further, as illustrated in FIG. 7, the first gate conductive layer 14d is provided between the gate insulating film 13 and the first interlayer insulating film 15 and is electrically connected to signal wiring lines (the gate line 14g, the source line 18f, and the like) extending toward the display region D. Further, as illustrated in FIG. 7, the second gate conductive layer 14e is provided between the gate insulating film 13 and the first interlayer insulating film 15 and, for example, is electrically connected to a signal terminal of the terminal portion T.

Note that, in the present embodiment, the organic EL display device 50a provided with the lead wiring lines 18j on the protrusions Ca and in the recesses Cb of the surface of the resin filling film 8a is exemplified. However, the device may be the organic EL display device 50aa provided with at least one of the plurality of lead wiring lines 18j on a protrusion Ca of the protrusions Ca of the surface of the resin filling film 8a, as illustrated in FIG. 11. Here, in the organic EL display device 50aa, as illustrated in FIG. 11, the plurality of lead wiring lines 18j are provided only on the protrusions Ca of the resin filling film 8a. According to this organic EL display device 50aa, with the lead wiring lines 18j not provided in the recesses Cb at relatively low positions where the metal film of the wiring line layers is likely to remain and provided only on the protrusions Ca at relatively high positions where the metal film of the wiring line layers is unlikely to remain as described above, it is possible to further suppress short-circuiting between the lead wiring lines 18j adjacent to each other.

The resin covering layer 19d is made of the same material as that of the flattening film 19a and formed in the same layer as that of the flattening film 19a.

Further, as illustrated in FIGS. 3 and 6, the organic EL display device 50a includes a plurality of peripheral photo spacers 22b provided in island shapes, protruding upward in the drawings, on the flattening film 19a in the frame region F. Each peripheral photo spacer 22b is made of the same material as that of the edge cover 22a and formed in the same layer as that of the edge cover 22a.

In the organic EL display device 50a described above, in each of the subpixels P, a gate signal is input to the first TFT 9a via the gate line 14g to turn on the first TFT 9a, a data signal is written in the gate electrode 14b of the second TFT 9b and the capacitor 9c via the source line 18f, and a current from the power source line 18g corresponding to a gate voltage of the second TFT 9b is supplied to the organic EL layer 23, whereby the light-emitting layer 3 of the organic EL layer 23 emits light to display an image. Note that, in the organic EL display device 50a, even when the first TFT 9a is turned off, the gate voltage of the second TFT 9b is held by the capacitor 9c. Thus, the light emission by the light-emitting layer 3 is maintained until the gate signal of the next frame is input.

Next, a method of manufacturing the organic EL display device 50a according to the present embodiment will be described. Here, the method of manufacturing the organic EL display device 50a according to the present embodiment includes a TFT layer formation process, an organic EL element layer formation process, and a sealing film formation process.

### TFT Layer Formation Process

First, for example, an inorganic insulating film (about 1000 nm in thickness) such as a silicon oxide film is formed on the resin substrate 10 formed on a glass substrate, for example, by plasma chemical vapor deposition (CVD), to form the base coat film 11.

Subsequently, for example, an amorphous silicon film (about 50 nm in thickness) is formed, by plasma CVD, on the substrate surface on which the base coat film 11 is formed, the amorphous silicon film is crystallized by laser annealing or the like to form a semiconductor film of a polysilicon film, and then the semiconductor film is patterned to form the semiconductor layers 12a and 12b.

Subsequently, an inorganic insulating film (about 100 nm in thickness) such as a silicon oxide film is formed on the substrate surface on which the semiconductor layers 12a and 12b are formed by, for example, plasma CVD, to form the gate insulating film 13.

Furthermore, an aluminum film (about 350 nm in thickness), a molybdenum nitride film (about 50 nm in thickness), and the like are sequentially formed on the substrate surface on which the gate insulating film 13 is formed by, for example, a sputtering method, and then a metal layered film thereof is patterned to form the gate line 14g, the gate electrodes 14a and 14b, the lower conductive layer 14c, the first gate conductive layer 14d, and the second gate conductive layer 14e.

Thereafter, the source region and the drain region are each formed on the semiconductor layer 12a (12b) by doping impurity ions using the gate electrodes 14a and 14b as a mask.

Subsequently, an inorganic insulating film (about 100 nm in thickness) such as a silicon oxide film is formed by, for example, plasma CVD, on the substrate surface on which the source region and the drain region are each formed on the semiconductor layer 12a (12b) to form the first interlayer insulating film 15.

Subsequently, an aluminum film (about 350 nm in thickness), a molybdenum nitride film (about 50 nm in thickness), and the like are sequentially formed on the substrate surface on which the first interlayer insulating film 15 is formed by, for example, a sputtering method, and then a metal layered film thereof is patterned to form the upper conductive layer 16c.

Furthermore, an inorganic insulating film (about 500 nm in thickness) such as a silicon oxide film is formed on the substrate surface on which the upper conductive layer 16c is formed by, for example, plasma CVD to form the second interlayer insulating film 17.

Subsequently, the second interlayer insulating film 17, the first interlayer insulating film 15, and the gate insulating film 13 are patterned to form the contact hole and the first slit Sa, and then the base coat film 11 is partially etched to form the second slit Sb, thereby forming the slit S.

Thereafter, a photosensitive polyimide resin is applied by, for example, a spin coating method or a slit coating method onto the substrate surface on which the slit S is formed, and then the coating film is pre-baked, exposed using a halftone mask and gray tone mask, developed, and post-baked to form, in a predetermined shape, the resin filling film 8a filling the slit S of the bending portion B.

Furthermore, the substrate surface on which the resin filling film 8a is formed is washed, a titanium film (about 30 nm in thickness), an aluminum film (about 300 nm in thickness), and a titanium film (about 50 nm in thickness) are sequentially formed by, for example, a sputtering method, on the substrate surface, and then a metal layered film thereof is patterned to form the wiring line layers such as the source electrodes 18a and 18c, the drain electrodes 18b and 18d, the source line 18f, the power source line 18g, the first frame wiring line 18h, the second frame wiring line 18i, and the lead wiring line 18j.

Finally, a photosensitive polyimide resin (about 2 µm in thickness) is applied, by, for example, a spin coating method or a slit coating method, onto the substrate surface on which the wiring line layers are formed, and then the coating film is pre-baked, exposed, developed, and post-baked to form the flattening film 19a and the like.

Thus, a TFT layer 20 can be formed as described above.

### Organic EL Element Layer Formation Process

The organic EL element 25 is formed by forming the first electrode 21a, the edge cover 22a, the organic EL layer 23 (the hole injection layer 1, the hole transport layer 2, the light-emitting layer 3, the electron transport layer 4, and the electron injection layer 5), and the second electrode 24 on the flattening film 19a of the TFT layer 20 formed in the TFT layer formation process described above by using a known method, whereby the organic EL element layer 30 is formed.

### Sealing Film Formation Process

First, an inorganic insulating film such as a silicon nitride film, a silicon oxide film, or a silicon oxynitride film, for example, is formed by plasma CVD using a mask, on the substrate surface on which the organic EL element layer 30 is formed in the organic EL element layer formation process described above, to form the first inorganic sealing film 36.

Subsequently, on the substrate surface on which the first inorganic sealing film 36 is formed, a film made of an organic resin material such as acrylic resin is formed, for example, by an ink-jet method, to form the organic sealing film 37.

Furthermore, an inorganic insulating film such as a silicon nitride film, a silicon oxide film, or a silicon oxynitride film, for example, is formed by plasma CVD on the substrate on which the organic sealing film 37 is formed by using a mask to form the second inorganic sealing film 38, thereby forming the sealing film 40.

Finally, after a protective sheet (not illustrated) is bonded on the substrate surface on which the sealing film 40 is formed, the glass substrate is peeled off from a lower surface of the resin substrate 10 by irradiation with laser light from the glass substrate side of the resin substrate 10, and then a protective sheet (not illustrated) is bonded on the lower surface of the resin substrate 10 from which the glass substrate was peeled.

Thus, the organic EL display device 50a of the present embodiment can be manufactured as described above.

As described above, according to the organic EL display device 50a of the present embodiment, the bending portion B of the frame region F is provided with the resin filling film 8a filling the slit S formed in the base coat film 11, the gate insulating film 13, the first interlayer insulating film 15, and the second interlayer insulating film 17. Then, on the resin filling film 8a, the plurality of lead wiring lines 18j are provided extending parallel with each other in a direction orthogonal to the extending direction of the bending portion B. Here, the resin filling film 8a is provided so that the surface thereof is increasingly lower than a surface of the first interlayer insulating film 17 outside of the slit S, from both end portions toward a central portion of the slit S in the width direction. Therefore, in the washing prior to formation of the wiring line layers such as the source line 18f, foreign matters are likely to accumulate on the surfaces of the inclined portions of the resin filling film 8a that are lower toward the central portion of the slit S, and the metal film of the wiring line layers is likely to remain on the surfaces of the inclined portions. However, the protrusions Ca and the recesses Cb, each extending in the direction orthogonal to the extending direction of the bending portion B, are alternately disposed in the extending direction of the bending portion B on the surface of the resin filling film 8a, making the metal film of the lead wiring lines 18j on the surface of the resin filling film 8a, even if residual in the recesses Cb relatively low in position, less likely to remain on the protrusions Ca relatively high in position. Then, of the plurality of lead wiring lines 18j, one of a pair of lead wiring lines 18j adjacent to each other is provided on the protrusion Ca, and the other of the pair of lead wiring lines 18j adjacent to each other is provided in the recess Cb, making it possible to suppress short-circuiting between the lead wiring line 18j provided on the protrusion Ca and the lead wiring line 18j provided in the recess Cb adjacent thereto. This makes it possible to suppress short-circuiting between the lead wiring lines 18j adjacent to each other, and thus suppress short-circuiting between wiring lines in the bending portion B of the frame region F.

### Second Embodiment

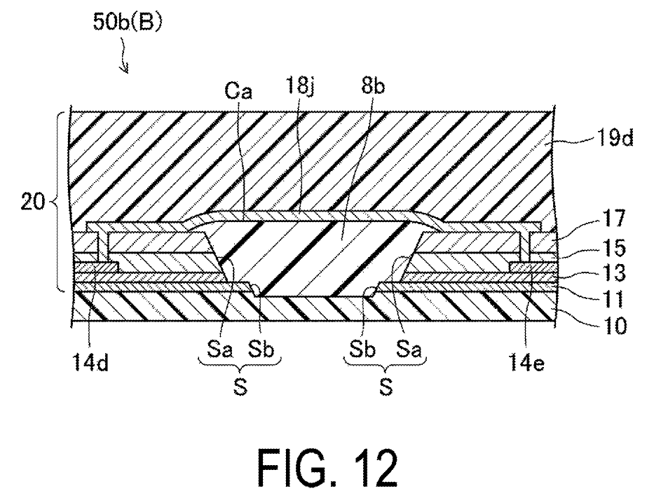

FIGS. 12-14 illustrate a second embodiment of a display device according to the disclosure. Here, FIGS. 12, 13, and 14 are cross-sectional views of the bending portion B of an organic EL display device 50b according to the present embodiment, and are views corresponding to FIGS. 8, 9, and 10 described in the first embodiment above. Note that, in the following embodiment, portions identical to those in FIGS. 1-11 are denoted by the same reference signs, and their detailed descriptions are omitted.

In the first embodiment described above, the organic EL display device 50a in which the surface of the resin filling film 8a at the central portion of the slit S in the width direction is lower than the surface of the second interlayer insulating film 17 is exemplified. However, in the present embodiment, the organic EL display device 50b in which the surface of the resin filling film 8b at the central portion of the slit S in the width direction is higher than the surface of the second interlayer insulating film 17 is exemplified.

As with the organic EL display device 50a of the first embodiment described above, the organic EL display device 50b includes the display region D provided in a rectangular shape and the frame region F provided in a frame-like shape surrounding the display region D.

Further, as with the organic EL display device 50a of the first embodiment described above, the organic EL display device 50b includes the resin substrate 10, the TFT layer 20 provided on the resin substrate 10, the organic EL element layer 30 provided on the TFT layer 20, and the sealing film 40 provided on the organic EL element layer 30.

Further, as with the organic EL display device 50a of the first embodiment described above, the organic EL display device 50b includes the first dam wall Wa and the second dam wall Wb in the frame region F.

In addition, as with the organic EL display device 50a of the first embodiment described above, the organic EL display device 50b includes the first frame wiring line 18h and the second frame wiring line 18i in the frame region F.

Further, as illustrated in FIGS. 12, 13, and 14, the organic EL display device 50b includes, in the bending portion B, a resin filling film 8b that fills the slit S formed in the base coat film 11, the gate insulating film 13, the first interlayer insulating film 15, and the second interlayer insulating film 17; the plurality of lead wiring lines 18j provided on the resin filling film 8b and the second interlayer insulating film 17; and the resin covering layer 19d provided covering the plurality of lead wiring lines 18j.

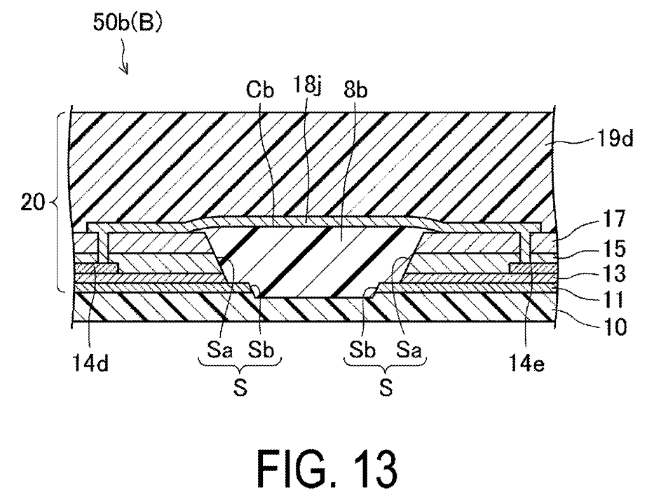

The resin filling film 8b is made of, for example, an organic resin material such as a polyimide resin. As illustrated in FIGS. 12 and 13, a surface of the resin filling film 8b is gradually increasingly higher than the surface of the second interlayer insulating film 17 outside of the slit S, from both end portions toward the central portion of the slit S in the width direction. Here, as illustrated in FIGS. 12, 13, and 14, the protrusions Ca and the recesses Cb, each extending in a direction orthogonal to the extending direction of the bending portion B, are alternately disposed in the extending direction of the bending portion B on the surface of the resin filling film 8b.

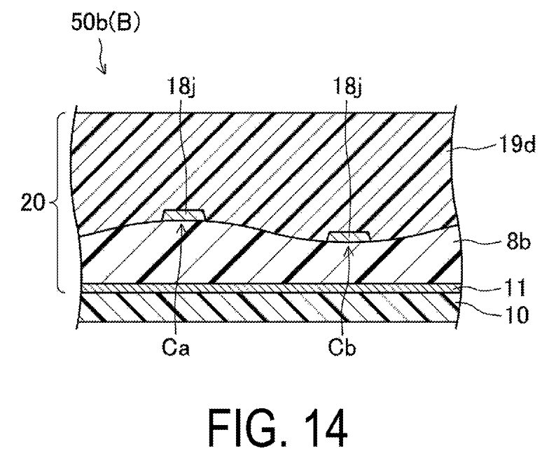

Of the plurality of lead wiring lines 18j, one of a pair of lead wiring lines 18j adjacent to each other is provided on the protrusion Ca as illustrated in FIGS. 12 and 14, and the other of the pair of lead wiring lines 18j adjacent to each other is provided in the recess Cb as illustrated in FIGS. 13 and 14. Note that, in the organic EL display device 50b, in the washing performed before formation of the wiring line layers such as the source line 18f, foreign matters are unlikely to accumulate on surfaces of inclined portions of the resin filling film 8b, which rises toward the central portion of the slit S, and thus the metal film of the wiring line layers is unlikely to remain on the inclined portions to begin with. However, even if metal film remains in the recesses Cb at relatively low positions on the surface of the resin filling film 8b, the metal film is even more unlikely to remain on the protrusions Ca of the resin filling film 18j at relatively high positions, making it possible to suppress short-circuiting between the lead wiring lines 18j adjacent to each other.

Note that, in the present embodiment, the organic EL display device 50b provided with the lead wiring lines 18j on the protrusions Ca and in the recesses Cb of the surface of the resin filling film 8b is exemplified. However, the lead wiring lines 18j may be provided only on the protrusions Ca of the surface of the resin filling film 8b.

Further, as with the organic EL display device 50a of the first embodiment described above, the organic EL display device 50b includes the plurality of peripheral photo spacers 22b provided on the flattening film 19a in island shapes in the frame region F.

As with the organic EL display device 50a of the first embodiment described above, the organic EL display device 50b described above is flexible and is configured to display an image by causing the light-emitting layer 3 of the organic EL layer 23 to emit light as appropriate, via the first TFT 9a and the second TFT 9b in each of the subpixels P.

The organic EL display device 50b of the present embodiment can be manufactured by modifying a surface shape of the resin filling film 8a in the manufacturing method of the organic EL display device 50a of the first embodiment described above.

As described above, according to the organic EL display device 50b of the present embodiment, the bending portion B of the frame region F is provided with the resin filling film 8b filling the slit S formed in the base coat film 11, the gate insulating film 13, the first interlayer insulating film 15, and the second interlayer insulating film 17. Then, on the resin filling film 8b, the plurality of lead wiring lines 18j are provided extending parallel with each other in a direction orthogonal to the extending direction of the bending portion B. Here, the resin filling film 8b is provided so that the surface thereof is increasingly higher than the surface of the first interlayer insulating film 17 outside of the slit S, from both end portions toward the central portion of the slit S in the width direction. Therefore, in the washing prior to formation of the wiring line layers such as the source line 18f, foreign matters are unlikely to accumulate on the surfaces of the inclined portions of the resin filling film 8b that are higher toward the central portion of the slit S, and the metal film of the wiring line layers is likely to remain on the surfaces of the inclined portions. Then, the protrusions Ca and the recesses Cb, each extending in the direction orthogonal to the extending direction of the bending portion B, are alternately disposed in the extending direction of the bending portion B on the surface of the resin filling film 8b, making the metal film of the lead wiring lines 18j on the surface of the resin filling film 8b, even if residual in the recesses Cb at relatively lower positions, even more unlikely to remain on the protrusions Ca relatively high in position. Then, of the plurality of lead wiring lines 18j, one of a pair of lead wiring lines 18j adjacent to each other is provided on the protrusion Ca and the other of the pair of lead wiring lines 18j adjacent to each other is provided in the recess Cb, making it possible to further suppress short-circuiting between the lead wiring line 18j provided on the protrusion Ca and the lead wiring line 18j provided in the recess Cb adjacent thereto. This makes it possible to further suppress short-circuiting between the lead wiring lines 18j adjacent to each other, and thus further suppress short-circuiting between wiring lines in the bending portion B of the frame region F.

### Other Embodiments

In each of the embodiments described above, the organic EL layer having a five-layer structure including the hole injection layer, the hole transport layer, the light-emitting layer, the electron transport layer, and the electron injection layer is exemplified, but the organic EL layer may have a three-layer structure including a hole injection-cum-transport layer, a light-emitting layer, and an electron transport-cum-injection layer, for example.

In each of the embodiments described above, the organic EL display device including the first electrode as an anode and the second electrode as a cathode is exemplified. However, the disclosure is also applicable to an organic EL display device in which the layered structure of the organic EL layer is reversed with the first electrode being a cathode and the second electrode being an anode.

In each of the embodiments described above, the organic EL display device in which the electrode of the TFT connected to the first electrode serves as the drain electrode is exemplified. However, the disclosure is also applicable to an organic EL display device in which the electrode of the TFT connected to the first electrode is referred to as the source electrode.

In each of the embodiments described above, the organic EL display device is exemplified as a display device. However, the disclosure can also be applied to a display device including a plurality of light-emitting elements driven by a current, for example, to a display device including quantum dot light-emitting diodes (QLEDs), which are a light-emitting element using a quantum dot-containing layer.

### Industrial Applicability

As described above, the disclosure is useful for a flexible display device.

1. A display device comprising:
a resin substrate;
a thin film transistor layer provided on the resin substrate and including an inorganic insulating film;
a flattening film provided on the thin film transistor layer and made of an organic material; and
a light-emitting element layer provided on the flattening film and including a plurality of first electrodes, a plurality of light-emitting functional layers, and a common second electrode sequentially layered corresponding to a plurality of subpixels constituting a display region,
wherein:
a frame region is provided surrounding the display region,
a terminal portion is provided at an end portion of the frame region,
a bending portion is provided between the display region and the terminal portion, the bending portion extending in an extending direction,
a slit is provided at the bending portion in the inorganic insulating film, the slit extending in the extending direction of the bending portion and exposing a surface of the resin substrate,
a resin filling film is provided at the bending portion, the resin filling film filling the slit,
a plurality of lead wiring lines is provided on the resin filling film, the plurality of lead wiring lines extending parallel with each other in a direction intersecting the extending direction of the bending portion,
the flattening film is provided with a trench exposing the inorganic insulating film in a region between the display region and the bending portion,
a resin covering layer made of the same material as that of the flattening film is provided on the plurality of lead wiring lines at the bending portion,
the inorganic insulating film includes a lower inorganic insulating film and an upper inorganic insulating film, and
at the bending portion, a width of a slit provided in the lower inorganic insulating film is smaller than a width of a slit provided in the upper inorganic insulating film.
